(19) United States
(12) Patent Application Publication
(10) Pub. No.: US 2017/0200658 A1
(43) Pub. Date: Jul. 13, 2017

(54) METHODS OF INSPECTING SUBSTRATES AND SEMICONDUCTOR FABRICATION METHODS INCORPORATING THE SAME

(71) Applicant: Samsung Electronics Co., Ltd., Suwon-si (KR)

(72) Inventors: Yusin Yang, Seoul (KR); Kang-Woong Ko, Seoul (KR); Sung Yoon Ryu, Suwon-si (KR); Gil-Woo Song, Hwaseong-si (KR); Sangkil Lee, Yongin-si (KR); Chungsam Jun, Suwon-si (KR); HyoungJo Jeon, Suwon-si (KR); Masahiro Horie, Suwon-si (KR)

(21) Appl. No.: 15/366,964

(22) Filed: Dec. 1, 2016

(30) Foreign Application Priority Data
Jan. 8, 2016 (KR) 10-2016-0002690

(51) Int. Cl. H01L 21/66; G01N 21/27; G01N 21/95

(52) U.S. Cl. CPC H01L 22/20; G01N 21/9501; G01N 21/27; G01N 2021/1748

(57) ABSTRACT

A method of inspecting a substrate includes irradiating light onto a substrate that has experienced a first process, obtaining spectral data of the light reflected from the substrate, detecting a defect region of the substrate from the spectral data, and extracting a first defect site that occurred in or during the first process from the defect region. Extracting the first defect site includes establishing an effective area where the first process affects the substrate, and extracting a superimposed area that is overlapped with the effective area from the defect region. The superimposed area is defined as the first defect site.

### CROSS-REFERENCE TO RELATED APPLICATIONS

This U.S. nonprovisional patent application claims priority under 35 U.S.C. §119 of Korean Patent Application 10-2016-0002690 filed on Jan. 8, 2016, the entire contents of which are hereby incorporated by reference.

### BACKGROUND

The present inventive concepts relate to methods of inspecting substrates, and, more particularly, to methods of inspecting substrates by employing an optical inspection apparatus that uses a spectroscopic spectrum to detect defects on a relatively large-sized substrate.

As semiconductor manufacturing processes become miniaturized and more complex, testing for and/or otherwise identifying defects that may occur in semiconductor devices may become more important. The detection of defects can lead to enhanced reliability and yield of semiconductor devices. The defects in semiconductor devices may be inspected using light.

### SUMMARY

Embodiments of the present inventive concepts provide methods of inspecting a substrate for detecting pattern variations and structural defects in a relatively large-sized area.

According to example embodiments of the present inventive concepts, a method of inspecting a substrate may comprise: irradiating light onto a substrate that has experienced a first process; obtaining spectral data of the light reflected from the substrate; detecting a defect region of the substrate from the spectral data; and extracting a first defect site that occurred in or otherwise corresponding to the first process from the defect region. Extracting the first defect site may comprise: establishing an effective area where the first process affects the substrate; and extracting, from the defect region, a superimposed area that is overlapped with the effective area. The superimposed area may be defined as the first defect site. A semiconductor device may be fabricated responsive to extracting the first defect site.

According to example embodiments of the present inventive concepts, a method of inspecting a substrate may comprise: irradiating light onto a target area of a substrate; obtaining spectral data of the light reflected from target area; comparing the obtained spectral data with a predetermined reference spectral data so as to quantify a difference therebetween; attaining a first defect map that indicates a defect region on the substrate based on the quantified difference; and fabricating a semiconductor device responsive to attaining the first defect map.

According to example embodiments of the present inventive concepts, a method of fabricating a semiconductor device includes detecting a defect region within a target area of a substrate based on spectral data indicated by light reflected from the target area, and identifying a defect site within the defect region as corresponding to a first fabrication process among a plurality of fabrication processes, where the detecting and identifying are operations performed by at least one controller. Identifying the defect site includes establishing an effective area within the target area, where the effective area includes patterns therein that are affected by the first fabrication process to a greater extent than other patterns within the target area; and determining an overlap between the effective area and the defect region, wherein the overlap is indicative of the defect site corresponding to the first fabrication process. The semiconductor device is fabricated responsive to identifying the defect site as corresponding to the first fabrication process.

### BRIEF DESCRIPTION OF THE DRAWINGS

The accompanying drawings are included to provide a further understanding of the inventive concepts, and are incorporated in and constitute a part of this specification. The drawings illustrate example embodiments of the present inventive concepts and, together with the description, serve to explain principles of the present inventive concepts. In the drawings:

FIG. 1 A shows an optical inspection apparatus according to exemplary embodiments of the present inventive concepts;

FIG. 1B shows a substrate as an example of an object which is inspected by the optical inspection apparatus of FIG. 1A;

FIG. 2A is a flow chart showing methods of inspecting a substrate using the substrate inspection apparatus;

FIG. 2B is a flow chart illustrating operations for detecting the defect region of FIG. 2A;

FIG. 2C is a flow chart illustrating operations for extracting the first defect site of FIG. 2A;

FIGS. 3A through 3D show a procedure illustrating operations shown in FIG. 2B; and

FIGS. 4A through 4E show the procedure illustrating operations shown in FIG. 2C.

### DETAILED DESCRIPTION OF EMBODIMENTS

Hereinafter, it will be described about an exemplary embodiment of the present inventive concepts in conjunction with the accompanying drawings.

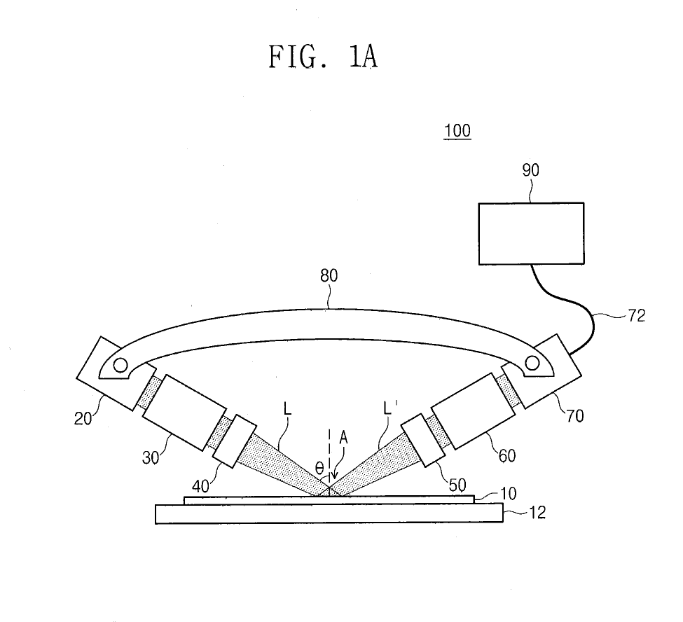

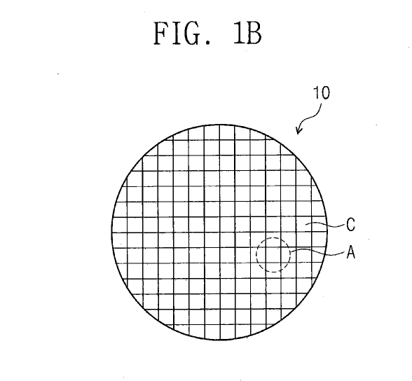

FIG. 1A shows an optical inspection apparatus 100 according to exemplary embodiments of the present inventive concepts. FIG. 1B shows a substrate 10 as an example of an object which is inspected by the optical inspection apparatus 100. The optical inspection apparatus 100 may optically inspect the substrate 10 placed on a holder 12. The optical inspection apparatus 100 may be hereinafter exemplarily explained as a substrate inspection apparatus. The substrate inspection apparatus 100 may comprise a light source 20, a monochromatic unit 30, a light incidence unit 40, a light receiving unit 50, an imaging unit 60, a detector 70, an angle handler 80, and a controller 90 (such as a computer processor). For example, the substrate inspection apparatus 100 may be a spectroscopic ellipsometer, but the present embodiment is not limited thereto. The substrate inspection apparatus 100 may be, for example, a vertical spectroscopic analyzer. The substrate 10 may be a wafer having a plurality of chips C.

Referring to FIGS. 1A and 1B, the light source 20 may irradiate an incident light L onto the target area A of the substrate 10. For example, the target area A may include at least one of the plurality of chips C. Alternatively, the target area A may correspond to a single chip C. The incident light L may be a broadband light. For example, the incident light L may include a bandwidth in a range from the ultraviolet ray band to the near infrared ray band.

The monochromatic unit 30 may include a monochromator. The monochromatic unit 30 may change a wavelength of the incident light L using an optic device such as a prism, a diffraction grating, or the like. The light incidence unit 40 may be positioned at the front of the monochromatic unit 30. In other words, the light incidence unit 40 may be positioned between the monochromatic unit 30 and the substrate 10 placed on the holder 12. The light incidence unit 40 may include a plurality of optical elements. For example, the light incidence unit 40 may include at least one of a polarizer, a lens, and a compensator.

The light receiving unit 50 may receive a reflected light L′ provided from the target area A. For example, the reflected light L′ may be reflected from the target area A. The light receiving unit 50 may include optical elements. For example, the light receiving unit 50 may include at least one of a polarizer, a lens, a compensator, and an analyzer. The imaging unit 60 may produce an image based on the reflected light L′ passed through the receiving unit 50, and an image data of the image may be transferred to the detector 70. The image data detected by the detector 70 may be transferred to the controller 90 through an optical fiber 72. For example, the image data may include spectral data. The angle handler 80 may adjust positions of the monochromatic unit 30, the light incidence unit 40, the light receiving unit 50, and the imaging unit 60. For example, the angle handler 80 may adjust an incidence angle θ of the incident light L, which may be varied according to one or more patterns to be measured. The incidence angle θ may be measured with reference to a direction that is perpendicular to the surface of the substrate 10.

The controller 90 may control the light source 20, the monochromatic unit 30, the light incidence unit 40, the light receiving unit 50, the imaging unit 60, the detector 70, and/or the angle handler 80. For example, the controller 90 may control positions of the light source 20, the monochromatic unit 30, the light incidence unit 40, the light receiving unit 50, the imaging unit 60, the detector 70, and the angle handler 80 based on a kind of inspection process, a profile (e.g., a profile of one or more patterns to be measured), and an inspection object. Additionally, the controller 90 may determine a wavelength of the incident light L and control a focal position (or a focal distance) of the imaging unit 60.

The controller 90 may receive the spectral data of the reflected light L′ from the detector 70 and analyze the received spectral data. For example, the spectral data may include at least one of a reflective spectrum, a transmitted spectrum, a Psi spectrum, and Delta spectrum. The controller 90 may analyze the spectral data to detect a defect region on the substrate 10. The controller 90 may selectively extract or otherwise distinguish a first defect site generated by a first process from the defect region on the substrate 10. The present inventive concepts will be discussed hereinafter with respect to an embodiment of procedure for detecting the defect region and extracting the first defect site using the controller 90.

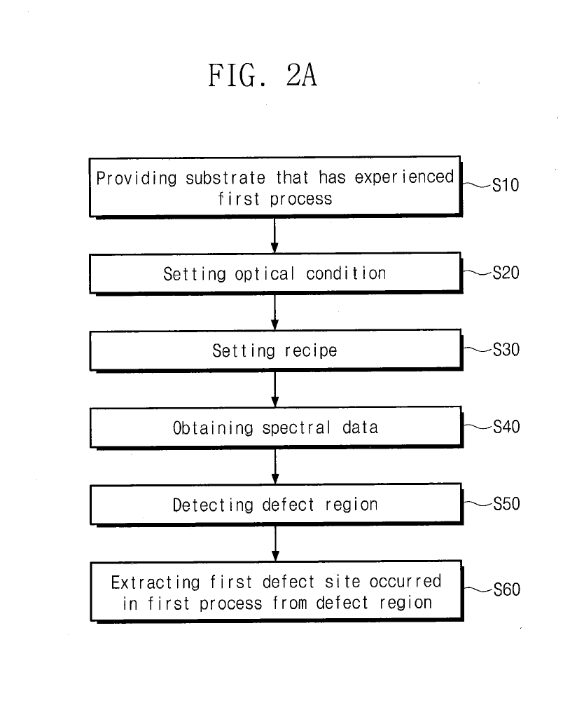

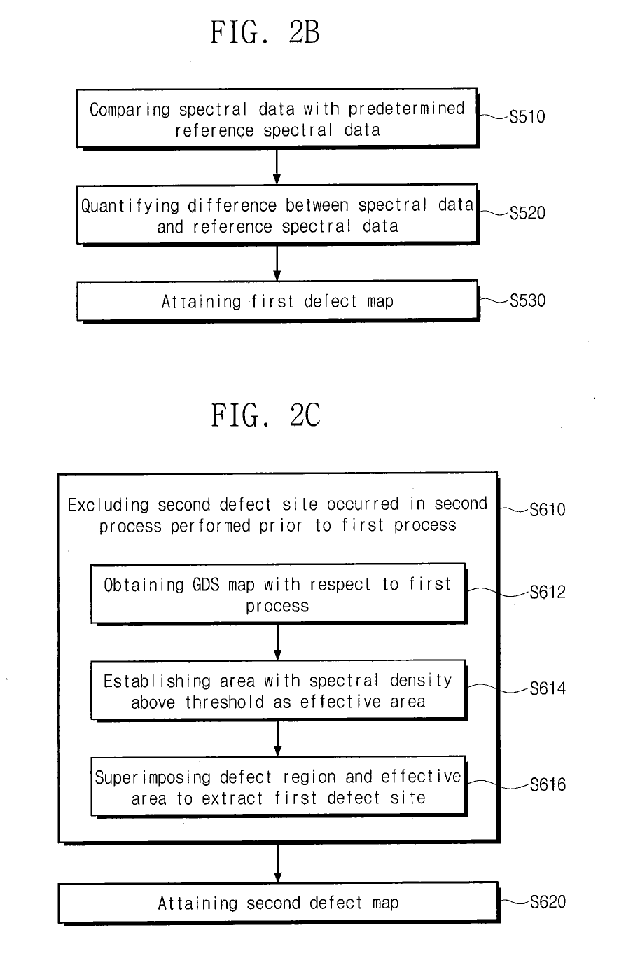

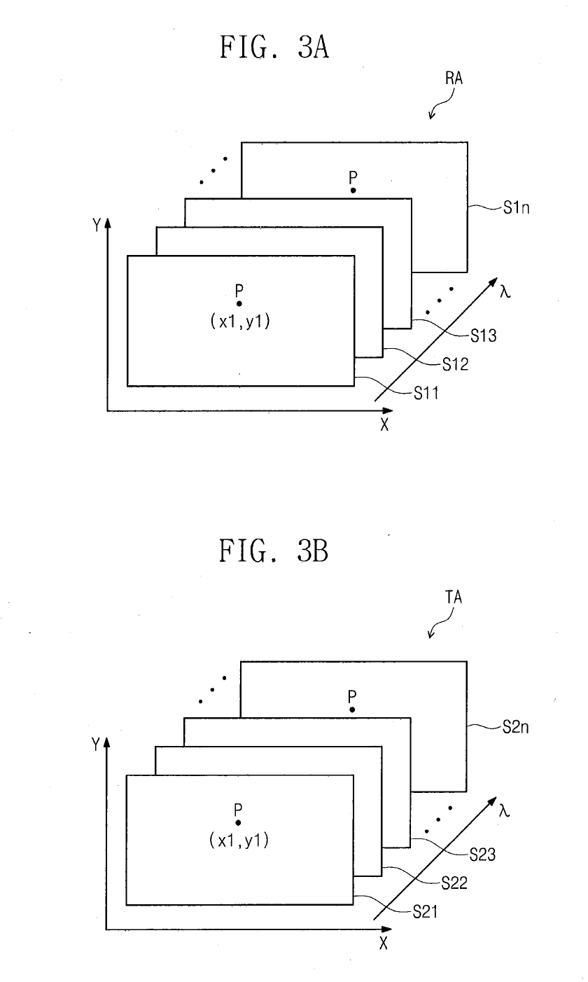

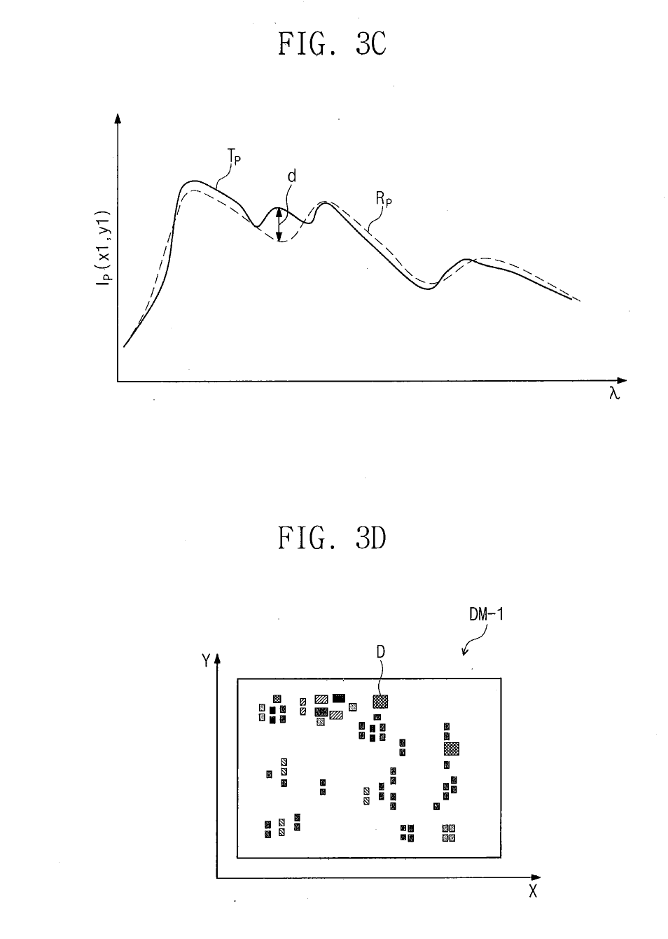

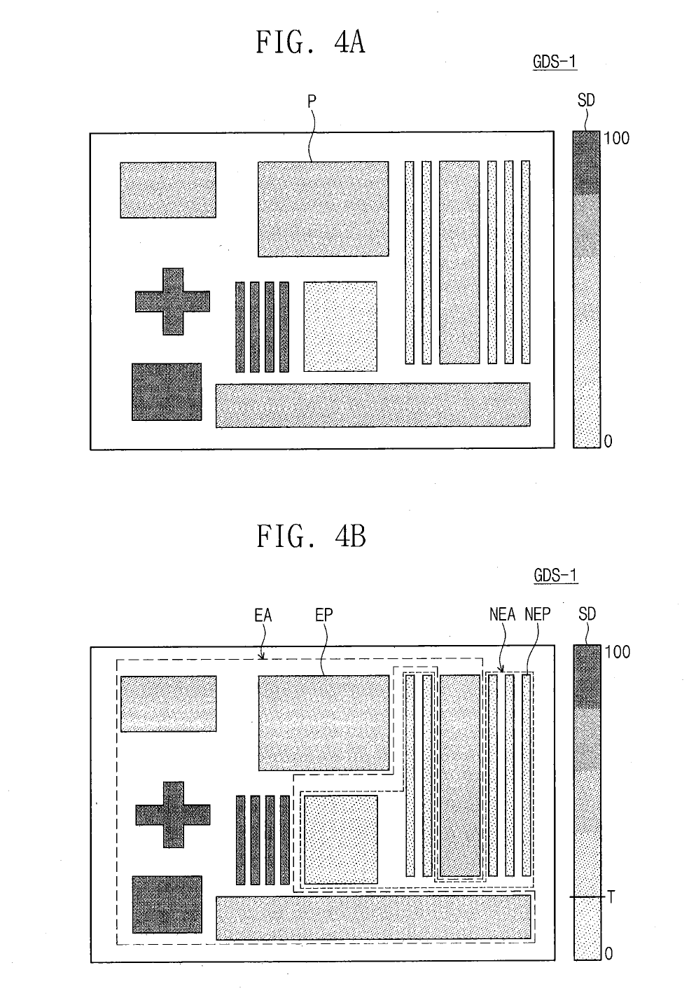

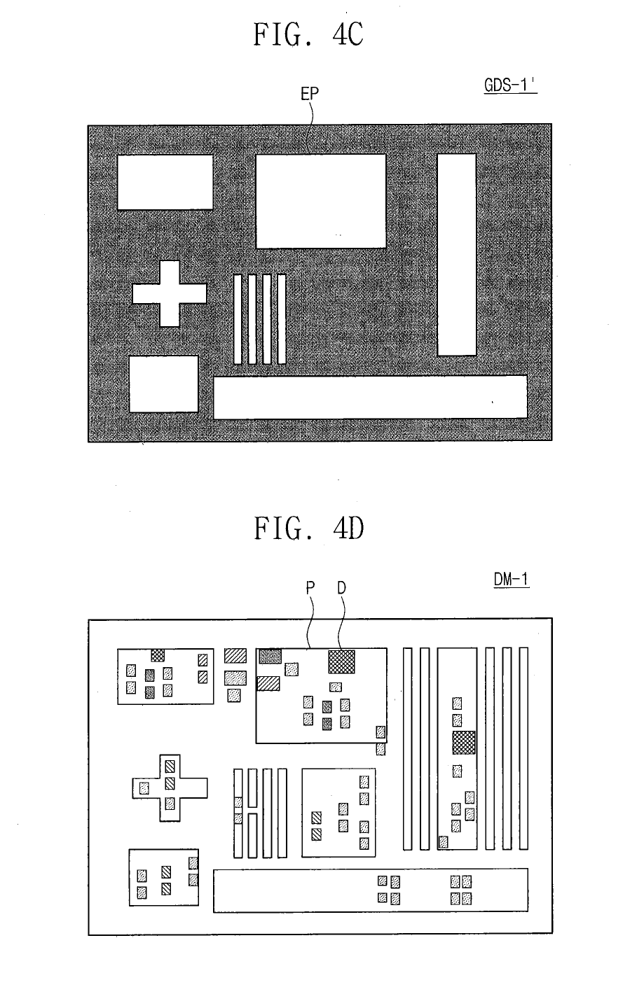

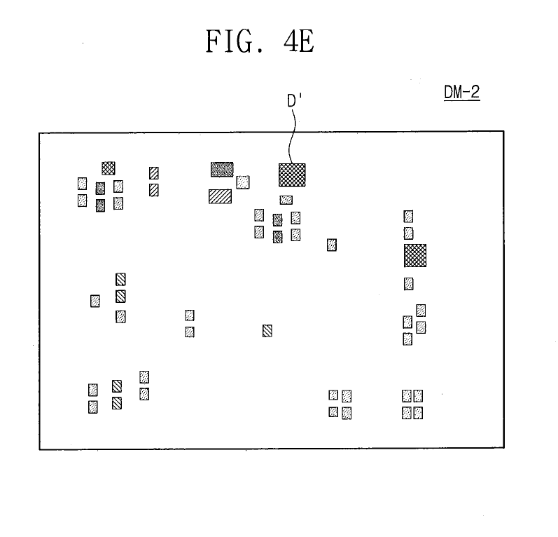

FIG. 2A is a flow chart showing methods of inspecting a substrate using the substrate inspection apparatus 100. FIG. 2B is a flow chart about the step of detecting the defect region of FIG. 2A. FIG. 2C is a flow chart about the step of extracting the first defect site of FIG. 2A. FIGS. 3A through 3D show the procedure about the step of FIG. 2B. FIGS. 4A through 4E show the procedure about the step of FIG. 2C. There will be discussed hereinafter methods of inspecting a substrate according to exemplary embodiments of the present inventive concepts with reference to FIGS. 2A through 4E.

Referring to FIGS. 1A and 2A, the substrate 10 may be provided as an inspection object. The substrate 10 may have experienced a first process (S10), which may be a particular type of fabrication process. The controller 90 may set an optical condition and an inspection recipe depending on a pattern of the substrate 10 and a profile of the pattern (S20 and S30). For example, the controller 90 may control angle θ of the incident light L. Thereafter, the controller 90 may perform to irradiate the incident light L onto the target area A and obtain the spectral data from the reflective light L′ (S40).

Referring to FIGS. 1A, 2A, 2B, 3A and 3B, the controller 90 may detect the defect region on the substrate 10 (S50). The controller 90 may compare the obtained spectral data TA of FIG. 3B with a predetermined reference spectral data RA of FIG. 3A (S510). For example, the spectral data RA and TA may have a shape of spectral cube acquired by irradiating multi-wavelength light onto the target area A. Spatial information on the target area A may be represented by the spectral cube having spatial axes of X and Y provided on the target area A and one spectral axis of wavelength λ on which images S1n or S2n (n is an integer) of the target area A are arranged in a widthwise direction for each wavelength λ.

Referring to FIGS. 1A, 2A, 2B, 3A, 3B, and 3C, the controller 90 may quantify a difference between the obtained spectral data TA of FIG. 3B and the predetermined reference spectral data RA (S520). The difference between the two spectral data may be measured by calculating a difference between the absolute values of the spectrums for each wavelength, calculating correlation between the two spectrums, calculating a difference between the slopes of the spectrums, etc., and then values calculated from one of the afore-mentioned measurements may be quantified into constants. FIG. 3C is a diagram representing two quantified spectrums Tp and Rp with respect to one particular point (designated by P of FIGS. 3A and 3B) on the target area A. For example, in FIG. 3C, the horizontal axis may indicate the wavelength λ and the vertical axis may denote the intensity. As shown in FIG. 3C, it may be possible to identify a difference d between the two spectrums. According to a process and an object used in an inspection methods, it may be possible to use spectral data with respect to a specific range of wavelength.

Referring to FIGS. 1A, 2A, 2B, 3C, and 3D, the controller 90 may obtain a first defect map DM-1 indicating a defect region D on the target area A based on the difference between the spectral data TA of FIG. 3B and the predetermined reference spectral data RA of FIG. 3A (S530). The first defect map DM-1 may show the difference d between the two spectrums depending on the spatial information on the target area A. For example, a color or brightness of the defect region D in the first defect map DM-1 may vary according to the difference d between the two spectrums. Selectively, the defect region D may be specified by depicting an area whose value, i.e., a quantified value of difference between the two spectrums, is above a predetermined critical difference or otherwise greater than a predetermined threshold. For the sake of clarity, patterns on the target area A will not be illustrated in the first defect map DM-1.

The reference spectral data may be established by selecting a reference region and obtaining spectral data thereabout. At least one zone with the lowest possible defects on the substrate 10 may be selected as the reference region, and spectral information about the at least one zone may be obtained to establish the reference spectral data for each site on the at least one zone. When a single zone of the substrate 10 is selected as the reference region, a defect in the single zone may become an error in the substrate inspection. It therefore may be advantageous to select a plurality of zones rarely having defects as the reference region. Furthermore, spectral data may be acquired on the basis of spectral information about the plurality of zones and a median value of spectral data for the plurality of zones may be selected as the reference spectral data, thereby reducing the effect of error.

Referring to FIGS. 1A, 2A, 2C and 4A through 4E, the controller 90 may selectively extract or otherwise distinguish a first defect site D′ of FIG. 4E caused by a first process from the defect regions D of FIG. 4D (S60). The defect regions D may include the first defect site D′ and a second defect site which may occur at or due to a second process performed prior to the first process. The first and second processes may be different, e.g., different semiconductor fabrication processes and/or performed at different times (for example, sequentially or in another process order). The controller 90 may exclude the second defect site caused by the second process and thus may selectively extract the first defect site D′ from the defect region D (S610) to distinguish defects attributable to the first process from defects attributable to the second process. Accordingly, it may be beneficial to establish criterion for differentiating the first defect site D′ from the second defect site. The second process may include a plurality of processes in some embodiments.

Referring to FIG. 4A, a layout format concerning the first process may be acquired and an effective parameter of the layout format may be established (S612). The layout format may be graphic data representing a layout of patterns P formed on the substrate 10 in a specific process. The layout format may be provided independently for each process. In the layout format, the effective parameter mainly affecting the patterns P in each process may be established. In an embodiment, the layout format may be a graphic design system (GDS) map GDS-1, and the effective parameter may be a spectral density SD. For example, the graphic design system map GDS-1 may be a layout format provided in a photolithography process. The graphic design system map GDS-1 may include information about patterns P and information about spectral density SD for respective information about patterns P. The spectral density SD may mean optical transmittance of respective patterns P. The spectral density SD may display relative contrast of transmittance required for each pattern P in the individual process. Accordingly, as shown in FIG. 4A, the graphic design system map GDS-1 for the first process may tell the spectral density SD required for each pattern P when the first process is performed. It may be construed that the first process may have a larger effect on patterns with relatively high spectral density SD than on patterns with relatively low spectral density SD.

Referring to FIG. 4B, the controller 90 may determine a threshold T of the spectral density SD and establish an area whose spectral density SD is above the threshold T as an effective area EA (S614). The controller 90 may further establish other area except the effective area EA as a non-effective area NEA. The effective area EA may include effective patterns EP which are relatively largely affected (i.e., are affected to a greater extent) by the first process, and the non-effective area NEA may include non-effective patterns NEP which are relatively less affected (i.e., are affected to a lesser extent) by the first process. The controller 90 may determine the threshold T on the basis of a kind of process and its object. This discrimination to distinguish the effective area EA from the non-effective area NEA about the first process may increase decision reliability of a weak point and a defect region on the substrate at the first process.

Referring to FIG. 4C, the controller 90 may mask the non-effective area NEA. Accordingly, a masked graphic design system map GDS-1′ may selectively reveal the effective patterns EP.

Referring to FIGS. 4C, 4D and 4E, the controller 90 may superimpose the masked graphic design system map GDS-1′ on a first defect map DM-1 to extract the first defect site D′ (S616). A preparatory process may be in advance performed to adjust size and match coordinates of the two maps GDS-1′ and DM-1 prior to the superimposition thereof. The first defect map DM-1 may be superimposed by the masked graphic design system map GDS-1′ serving as a mask, and thus a superimposed area overlapped with the masked graphic design system map GDS-1′ may be extracted from the defect region D of the first defect map DM-1. In an embodiment, the superimposed area may be defined as the first defect site D′. Through the afore-mentioned steps, the controller 90 may obtain a second defect map DM-2 that indicates the first defect site D′ (S620). Not shown in figures, the second defect map DM-2 may include a pattern depending on abnormality. The masking process may be performed to the graphic design system map GDS-1 according to the effective parameter affected mainly by the first process such that it may be possible to exclude an effect of the second process and/or underlying structural feature of target sample.

Next, the controller 90 may acquire a map showing a defect region on the substrate 10. The defect region may include an inherent defect region on the substrate 10 or a foreign defect region occurred at a specific process.

Additionally, in case that GDS maps related to the first and second processes are analogous to each other, the controller 90 may obtain defect maps including defect regions which are extracted after the first and second processes, respectively, and compare the defect maps to determine that the first defect site is attributable to (e.g., occurred in or during) the first process.

According to exemplary embodiments of the present inventive concepts, it may be possible to individually determine areas with higher probability of defect occurred in or otherwise corresponding to each process and thus to continuously carry out measurement optimal to the each process. Through this, it may be advantageous to easily determine whether the related process is defective and further to improve development speed and fabrication yield through process enhancement. In addition, abnormality of non-repetitive pattern may be recognized and modeling thereof may be skipped, which may swiftly detect pattern changes and structural failure on a large-sized zone.

Embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present inventive concepts.

The flow charts shown in the figures illustrate the architecture, functionality, and operations of embodiments of hardware and/or software according to various embodiments of the present inventive concepts. It will be understood that each block of the flow chart and/or block diagram illustrations, and combinations of blocks in the flow chart and/or block diagram illustrations, may be implemented by computer program instructions and/or hardware operations. In this regard, each block represents a module, segment, or portion of code, which comprises one or more executable instructions for implementing the specified logical function(s). It should be noted that, in other implementations, the function(s) noted in the blocks may occur out of the order noted in the figures. For example, two blocks shown in succession may, in fact, be executed substantially concurrently, or the blocks may sometimes be executed in the reverse order, depending on the functionality involved.

The computer program instructions may be provided to a processor of a general purpose computer, a special purpose computer, or other programmable data processing apparatus to produce a machine, such that the instructions, which execute via the processor of the computer or other programmable data processing apparatus, create means for implementing the functions specified in the flowchart and/or block diagram block or blocks. The computer program instructions may also be stored in a computer usable or computer-readable memory that may direct a computer or other programmable data processing apparatus to function in a particular manner, such that the instructions stored in the computer usable or computer-readable memory produce an article of manufacture including instructions that implement the function specified in the flowchart and/or block diagram block or blocks.

Effects of the present inventive concepts are not limited to the aforementioned effects. Other effects, which are not mentioned above, will be apparently understood by the person skilled in the art from the foregoing descriptions and accompanying drawings.

Although the present inventive concepts have been described in connection with embodiments illustrated in the accompanying drawings, the present inventive concepts are not limited thereto. It will be apparent to those skilled in the art that various substitutions, modifications, and changes may be thereto without departing from the scope and spirit of the inventive concepts.

What is claimed is:

1. A method of fabricating a semiconductor device, the method comprising:
performing a first process to a substrate; and
inspecting the substrate that has experienced the first process, wherein the inspecting the substrate comprises:
irradiating light onto the substrate;
obtaining spectral data of the light reflected from the substrate;
detecting a defect region of the substrate from the spectral data; and
extracting a first defect site corresponding to the first process from the defect region, wherein extracting the first defect site comprises:
establishing an effective area in which the first process affects the substrate; and
extracting, from the defect region, a superimposed area that overlaps the effective area, wherein the superimposed area is defined as the first defect site.

2. The method of claim 1, wherein establishing the effective area comprises:
acquiring a layout format with respect to the first process;
establishing an effective parameter in the layout format;
setting a threshold of the effective parameter; and
establishing an area whose effective parameter is above the threshold as the effective area on the substrate.

3. The method of claim 2, wherein the layout format includes a graphic design system (GDS) and the effective parameter includes a spectral density.

4. The method of claim 1, wherein detecting the defect region comprises:
comparing the spectral data with a predetermined reference spectral data; and
quantifying a difference between the spectral data and the reference spectral data.

5. The method of claim 4, wherein detecting the defect region further comprises attaining a first defect map that indicates the defect region on the substrate.

6. The method of claim 5, wherein extracting the first defect site comprises superimposing the first defect map and the effective area having the effective parameter above the threshold.

7. The method of claim 6, wherein extracting the first defect site further comprises attaining a second defect map that indicates the first defect site on the substrate.

8. The method of claim 1, wherein the spectral data includes at least one of a reflective spectrum, a transmitted spectrum, a Psi spectrum, and Delta spectrum.

9. A method of inspecting a substrate, the method comprising:
irradiating light onto a target area of a substrate;
obtaining spectral data of the light reflected from the target area;
comparing the spectral data that was obtained with a predetermined reference spectral data to quantify a difference therebetween; and
attaining a first defect map that indicates a defect region on the substrate based on the quantified difference; and
fabricating a semiconductor device responsive to attaining the first defect map.

10. The method of claim 9, wherein
the substrate has experienced a first process, and
the method further comprises extracting a first defect site from the defect region, wherein the first defect site occurred in the first process.

11. The method of claim 10, wherein extracting the first defect site further comprises excluding a second defect site on the substrate, wherein the second defect site occurred in a second process performed prior to the first process.

12. The method of claim 10, wherein extracting the first defect site comprises:
acquiring a layout format of the substrate with respect to the first process;
establishing an effective parameter in the layout format;
setting a threshold of the effective parameter;
establishing an area whose effective parameter is above the threshold as an effective area on the substrate; and
defining a superimposed area, which is extracted from the defect region and overlapped with the effective area, as the first defect site.

13. The method of claim 12, wherein the layout format includes a graphic design system (GDS) and the threshold includes a spectral density.

14. The method of claim 10, further comprising attaining a second defect map that indicates the first defect site on the substrate.

15. The method of claim 9, wherein the substrate comprises a wafer and the target area comprises at least one of a plurality of chips.

16. A method of fabricating a semiconductor device, the method comprising:
detecting a defect region within a target area of a substrate based on spectral data indicated by light reflected from the target area; and
identifying a defect site within the defect region as corresponding to a first fabrication process among a plurality of fabrication processes, wherein the identifying the defect site comprises:
establishing an effective area within the target area, the effective area comprising patterns therein that are affected by the first fabrication process to a greater extent than other patterns within the target area; and
determining an overlap between the effective area and the defect region, wherein the overlap is indicative of the defect site corresponding to the first fabrication process,
wherein the detecting and the identifying comprise operations performed by at least one controller, the method further comprising:
fabricating the semiconductor device responsive to identifying the defect site as corresponding to the first fabrication process.

17. The method of claim 16, wherein establishing the effective area comprises:
acquiring a layout format corresponding to the first fabrication process, wherein the layout format indicates an effective parameter for the patterns affected by the first fabrication process,
wherein, in the effective area, the effective parameter for the patterns exceeds a threshold.

18. The method of claim 17, wherein the plurality of fabrication processes comprises the first fabrication process and a second fabrication process that is temporally different from the first fabrication process,
wherein the defect region includes the defect site as a first defect site and further includes a second defect site corresponding to the second fabrication process, and
wherein identifying the first defect site as corresponding to the first fabrication process comprises excluding the second defect site corresponding to the second fabrication process based on the effective parameter for the patterns affected by the first fabrication process.

19. The method of claim 16, wherein:
detecting the defect region comprises generating a first defect map indicative of the defect region within the target area based on a difference between the spectral data and reference data; and
determining the overlap between the effective area and the defect region comprises generating a second defect map indicative of the defect site as corresponding to the first fabrication process based on superimposing the effective area and the first defect map,
wherein generating the second defect map comprises:
establishing a non-effective area within the target area, the non-effective area comprising the other patterns that are affected by the first fabrication process to a lesser extent than the patterns in the effective area;
masking the non-effective area to provide a masked map that selectively reveal the patterns in the effective area; and
superimposing the masked map on the first defect map to indicate the defect site.

20. The method of claim 16, wherein identifying the defect site as corresponding to a first fabrication process comprises:
obtaining respective defect maps including defect regions based on differences between the spectral data and reference data after respective ones of the fabrication processes, and
comparing the respective defect maps to determine that the defect site occurred in the first fabrication process among the plurality of fabrication processes.
